(19) United States
(12) Patent Application Publication
(10) Pub. No.: US 2026/0206626 A1
(43) Pub. Date: Jul. 16, 2026

(54) Integrated Circuit (IC) Module, Multi-Interface IC Card, and Methods of Forming Same

(71) Applicant: ACT IDENTITY TECHNOLOGY LIMITED, Kwai Chung, New Territories (HK)

(72) Inventors: Shek Tong Lam, Kwai Chung, New Territories (HK); Lan Deng, Kwai Chung, New Territories (HK)

(21) Appl. No.: 19/136,146

(22) PCT Filed: Nov. 16, 2023
(86) PCT No.: PCT/CN2023/131971

§ 371 Date: Jun. 5, 2025

Related U.S. Application Data
(60) Provisional application No. 63/434,200, filed on Dec. 21, 2022.

(51) Int. Cl. H10W 70/68; G06K 19/077; H10W 70/05; H10W 70/40; H10W 70/685

(52) U.S. Cl. CPC H10W 70/682; G06K 19/07722; H10W 70/05; H10W 70/479; H10W 70/685

(57) ABSTRACT

An integrated circuit (IC) module (100) is disclosed as including a lower substrate layer (104) with a hole (106), an IC chip (108) received within the hole, and an upper substrate layer (102) fixedly connected with the lower substrate layer and electrically connected with the IC chip, the upper substrate layer including a planar front major surface (109) and a planar back major surface (110) which are parallel with each other, the planar back major surface including a plurality of connection points (114) electrically connected with the IC chip, the plurality of connection points being electrically connected with a plurality of connection points (112a-f, 113a-d) on the planar front major surface of the upper substrate layer, and the IC module being in the shape of a prism, a cylinder, or an elliptical cylinder.

### FIELD OF THE INVENTION

This invention relates to an integrated circuit (IC) module, a multi-interface integrated circuit (IC) card (also called a “Smart Card”) with such an IC module, and methods of forming the IC module and the IC card.

### BACKGROUND OF THE INVENTION

FIGS. 1 and 2 show a prior art arrangement of forming an integrated circuit (IC) card (also called a “Smart Card”), generally designated as 10.

The smart card 10 has a plastic card 12 in which a cavity 14 is formed, e.g. by milling. A loop antenna coil 16 is provided within the plastic card 12, to allow contactless (wireless) transmission of data between the smart card 10 and an outside reader (not shown).

A conventional IC module (generally designated as 18) includes and is fixedly engaged with a lead-frame 20. When the smart card 10 is duly assembled, the lead-frame 20 is exposed on one side to the outside to allow transmission of data when the lead-frame 20 is brought into electrical connection when in contact with an outside reader (not shown). The IC module 18 is fixedly engaged and electrically connected with an IC chip 22, and the IC chip 22 is protected by a globe 24 made of a protection material.

It can be seen that the cavity 14 is of two levels. A lower level is narrower and of a smaller area than an upper level. The lower level is for receiving the IC chip 22 and the globe 24 and the upper level is for receiving and supporting the lead-frame 20.

To fixedly engage the IC module 18 with the plastic card 10 and to establish electrical connection between the lead-frame 20 and the loop antenna coil 16, electrically conductive glue 26 is attached to the lead-frame 20, and hot-melt tapes 28 are positioned between the conductive glue 26 and exposed regions of the loop antenna coil 16. Upon application of heat, the IC module 18 is fixedly engaged (embedded in) and electrically connected with the plastic card 12, as shown in FIG. 2.

The conventional IC card 10 and its production method suffer from the following disadvantages:
1. The IC module 18 is in physical contact with and supported by the plastic card 12 only around a relatively narrow peripheral area. Such compromises the physical connection of the IC module 18 with the plastic card 12, and thus the physical strength of the IC card 10.
2. It is necessary to form the two-level cavity 14, thus complicating the production method.
3. A space 30 exists in the lower level of the cavity 14, further compromising the physical strength of the IC card 10. Moisture may seep into the cavity 14, jeopardizing the proper functioning of the IC card 10.

It is thus an objective of the present invention to provide an IC module, a multi-interface IC card, and methods of forming the IC module and the IC card in which at least one of the above shortcomings is mitigated, or at least to provide a useful alternative to the public.

### SUMMARY OF THE INVENTION

According to a first aspect of the present invention, there is provided an integrated circuit (IC) module, including a first substrate layer with a hole, an integrated circuit (IC) chip received within said hole of said first substrate layer, and a second substrate layer fixedly connected with said first substrate layer and electrically connected with said IC chip, wherein said second substrate layer includes a first substantially planar major surface and a second substantially planar major surface which are substantially parallel with each other, wherein said first major surface of said second substrate layer includes a first plurality of connection points electrically connected with said IC chip, wherein said first plurality of connection points are electrically connected with a second plurality of connection points on said second major surface of said second substrate layer, and wherein said IC module is in the shape of a prism, a cylinder, or an elliptical cylinder.

According to a second aspect of the present invention, there is provided a multi-interface integrated circuit (IC) card, including at least one IC module including a first substrate layer with a hole, an integrated circuit (IC) chip received within said hole of said first substrate layer, and a second substrate layer fixedly connected with said first substrate layer and electrically connected with said IC chip, wherein said second substrate layer includes a first substantially planar major surface and a second substantially planar major surface which are substantially parallel with each other, wherein said first major surface of said second substrate layer includes a first plurality of connection points electrically connected with said IC chip, wherein said first plurality of connection points are electrically connected with a second plurality of connection points on said second major surface of said second substrate layer, and wherein said IC module is in the shape of a prism, a cylinder, or an elliptical cylinder, at least a third substrate layer fixedly engaged with said IC module, and a lead-frame fixedly engaged with said third substrate and electrically connected with said IC module, wherein said third substrate layer includes a first communication interface electrically connected with a first connection point and a second connection point of said second plurality of connection points on said second major surface of said second substrate layer of said IC module and a second communication interface electrically connected with a third connection point and a fourth connection point of said second plurality of connection points on said second major surface of said second substrate layer of said IC module.

According to a third aspect of the present invention, there is provided a method of forming an integrated circuit (IC) module, including providing a first substrate layer with a hole, positioning an integrated circuit (IC) chip within said hole of said first substrate layer, and providing a second substrate layer with a first substantially planar major surface and a second substantially planar major surface which are substantially parallel with each other, fixedly connecting said second substrate layer with said first substrate layer, electrically connecting a first plurality of connection points on said first major surface of said second substrate layer with said IC chip, wherein said first plurality of connection points are electrically connected with a second plurality of connection points on said second major surface of said second substrate layer, and wherein said IC module is in the shape of a prism, a cylinder, or an elliptical cylinder.

According to a fourth aspect of the present invention, there is provided a method of forming an integrated circuit (IC) card, including providing a first substrate layer with a hole, positioning an integrated circuit (IC) chip within said hole of said first substrate layer, and providing a second substrate layer with a first substantially planar major surface and a second substantially planar major surface which are substantially parallel with each other, fixedly connecting said second substrate layer with said first substrate layer, electrically connecting a first plurality of connection points on said first major surface of said second substrate layer with said IC chip, wherein said first plurality of connection points are electrically connected with a second plurality of connection points on said second major surface of said second substrate layer, and wherein said IC module is in the shape of a prism, a cylinder, or an elliptical cylinder, fixedly engaging said IC module with a third substrate layer, electrically connecting a loop antenna coil of third substrate layer with a first connection point and a second connection point of said second plurality of connection points on said second major surface of said second substrate layer of said IC module, fixedly engaging a lead-frame with said third substrate, and electrically connecting said lead-frame with said IC module.

### BRIEF DESCRIPTION OF THE DRAWINGS

Embodiments of the present invention will now be described, by way of examples only, with reference to the accompanying drawings, in which:

FIG. 1 shows an exploded schematic sectional view of a prior art integrated circuit (IC) card;

FIG. 2 shows a schematic sectional view of the prior art IC card of FIG. 1;

FIG. 3 shows a method of forming a multi-interface integrated circuit (IC) module according to an embodiment of the present invention;

FIG. 4 shows a front major surface of an upper substrate layer of FIG. 3;

FIG. 5 shows a back major surface of the upper substrate layer of FIG. 3;

FIG. 6 shows the IC module of FIG. 3 fixedly engaged with an inlay substrate layer;

FIG. 7 shows the inlay substrate layer of FIG. 6 (fixedly engaged with the IC module of FIG. 3) sandwiched between an upper substrate and a lower substrate;

FIG. 8 shows a multi-layered structure with the inlay substrate layer of FIG. 7;

FIG. 9 shows a front view of the lead-frame of FIG. 8;

FIG. 10 shows a back view of the lead-frame of FIG. 9;

FIG. 11 shows an enlarged view showing the connection between the lead frame and the IC module of FIG. 3 in the multi-layered structure of FIG. 8;

FIG. 12 shows a perspective view of a multi-interface integrated circuit (IC) module according to the present invention;

FIG. 13 shows an exploded schematic sectional view of the IC card of FIG. 12; and

FIG. 14 shows a schematic sectional view of the IC card of FIG. 12.

### DESCRIPTION OF EMBODIMENTS OF THE INVENTION

FIG. 3 shows a method of forming a multi-interface (such as dual-interface) integrated circuit (IC) module, generally designated as 100, according to an embodiment of the present invention

The IC module 100 includes an upper substrate layer 102, a lower substrate layer 104 with a hole 106, and an IC chip 108. The IC chip 108 is received within the hole 106, and the IC module 100 is formed by laminating the upper substrate layer 102 and the bottom substrate layer 104 with each other. It should be understood that, in addition to the upper substrate layer 102 and bottom substrate layer 104, the IC module 100 may include one or more substrate layers, whether between the upper substrate layer 102 and bottom substrate layer 104, or outer of the upper substrate layer 102 and bottom substrate layer 104.

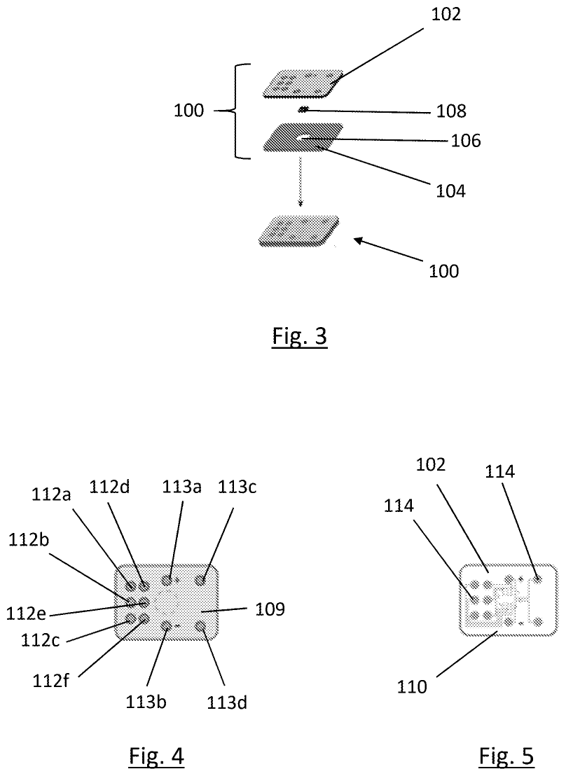

FIGS. 4 and 5 show, respectively, a planar front major surface 109 and a planar back major surface 110 of the upper substrate layer 102, which are parallel with each other. The front surface 109 has a total of ten electrical connection points 112a, 112b, 112c, 112d, 112e and 112f (collectively, “112a-f”) and 113a, 113b, 113c and 113d (collectively, “113a-d”), which are in respective electrical connection with ten corresponding electrical connection points 114 on the back surface 110. The IC chip 108 is physically and electrically connected with the connection points 114 on the back surface 110 of the upper substrate layer 102 which are in electrical connection with the connection points 112a-f on the front surface 109. The front surface 109 of the upper substrate layer 102 is also the front surface of the IC module 100. The electrical connection points 112a-f are for electrical connection with the six pins of the IC chip 108. The total number of the electrical connection points may be more than ten, e.g. when an 8-pin IC chip is used for forming the IC module 100.

All ten electrical connection points 112a-f, 113a-d are shown in FIG. 4 as being on the front surface 109 of the upper substrate layer 102. If deemed appropriate, some of these electrical connection points, e.g. the electrical connection points 113a-d, may be provided on the back surface 110 of the upper substrate layer 102.

The IC module 100 is in the shape of a short generally rectangular prism, although alternatively it may be in the form of a cylinder, or an elliptical cylinder. In the form of the short generally rectangular prism as shown in FIG. 3, the IC module 100 has two opposite planar major surfaces (one of which being the front surface 109 of the upper substrate layer 102) joined with each other by a surrounding side wall which is perpendicular to the two opposite planar major surfaces.

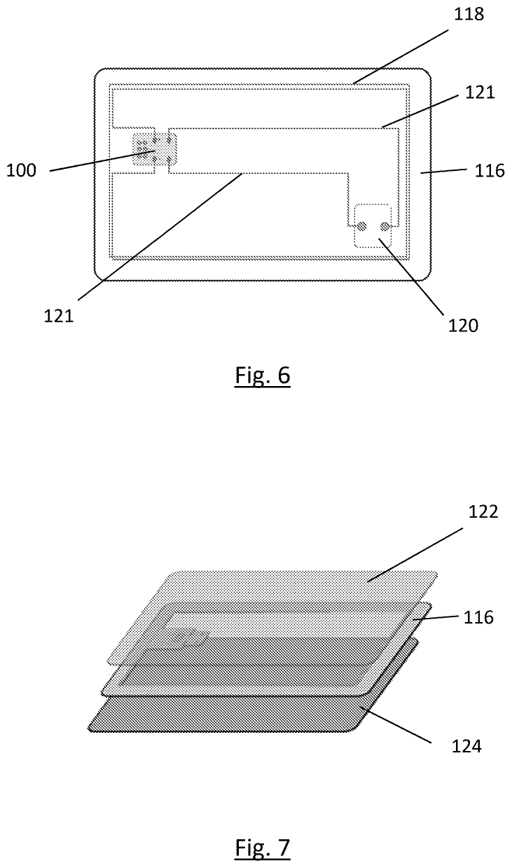

As shown in FIG. 6, the IC module 100 is fixedly engaged with an inlay substrate layer 116 with the front surface 109 of the IC module 100 exposed to the outside environment. A loop antenna coil 118 made of copper is formed on the inlay substrate layer 116. Two free ends of the loop antenna coil 118 are respectively electrically connected with the electrical connection points 113a and 113b on the front surface 109 of the IC module 100, thus allowing contactless (wireless) transmission of data between a smart card formed with the inlay substrate layer 116 and a card reader (not shown).

A second communication interface 120 is shown as provided on the inlay substrate layer 116, and in electrical connection with the electrical connection points 113c and 113d on the front surface 109 of the IC module 100 via two electric wires 121, thus allowing operation of the second communication interface 120 as a further interface of the resultant smart card with the outside environment. Of course, if the second communication interface 120 has more electric points for connection with the IC module 100, more electrical connection points may be provided on the IC module 100, and three or more electric wires 121 may be provided for electrically connecting the IC module 100 with the second communication interface 120. The second communication interface 120 may be a finger-print sensor for obtaining finger-print details from a finger (such as a thumb) in physical contact with the finger-print sensor. The second communication interface 120 may alternatively be a light-emitting diode (LED) module for emitting light to the outside environment for communication purposes.

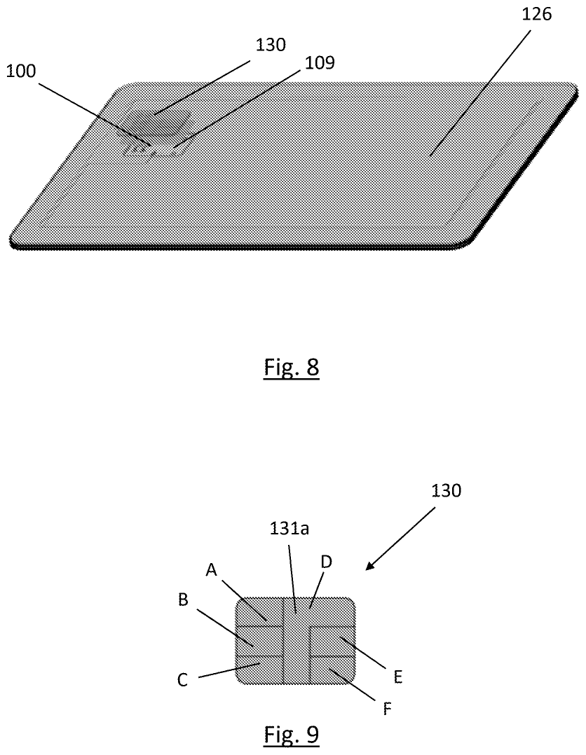

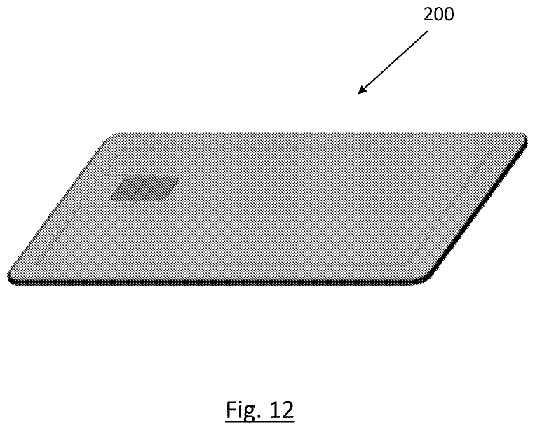

To form a multi-interface (e.g., dual-interface) IC card according to the present invention (generally designated as 200 in FIG. 12), the inlay substrate layer 116 is then sandwiched between an upper substrate 122 and a lower substrate 124 (as shown in FIG. 7), and is fixedly engaged with the upper substrate 122 and the lower substrate 124, e.g. by lamination, to form a multi-layered structure 126 (as shown in FIG. 8).

The resultant multi-layered structure 126 is then processed, e.g. by a milling machine, to form a cavity 128 (see FIG. 13) through the upper substrate 122 until the front major surface 109 of the IC module 100 and electrical connection points 112a-f and 113a-d are exposed to the outside environment. A lead-frame (not attached with an IC chip, and not previously engaged with the IC module 100) 130 is then positioned within the cavity 128 to be fixedly engaged with the front major surface 109 of the IC module 100.

As shown in more detail in FIG. 13, the lead-frame 130 has an upper major surface 131a made at least partly of an electrically conductive material, such as a metal, e.g. copper, and an opposite bottom major surface 131b also made at least partly of an electrically conductive material, such as a metal, e.g. copper. The upper major surface 131a and the lower major surface 131b are electrically connected with each other via an electrically conducting through-hole 131c (e.g. by electroplating the surrounding wall of the through-hole 131c with an electrically conducting material, such as a metal, e.g. copper) which runs through the body of the lead-frame 130. By way of such an arrangement, the upper major surface 131a of the lead-frame 130 may act as a physical interface with an outside card reader (not shown), whereby electrical connection may be established between the card reader and the IC chip 108 of the IC module 100, via the through-hole 131c, the bottom major surface 131b, the appropriate connection points 114 on the back surface 110 of the upper substrate layer 102 of the IC module 100, an electrically conductive adhesive material 132 (to be discussed below), and the connection points 112a-f on the front major surface 109 of the IC module 100.

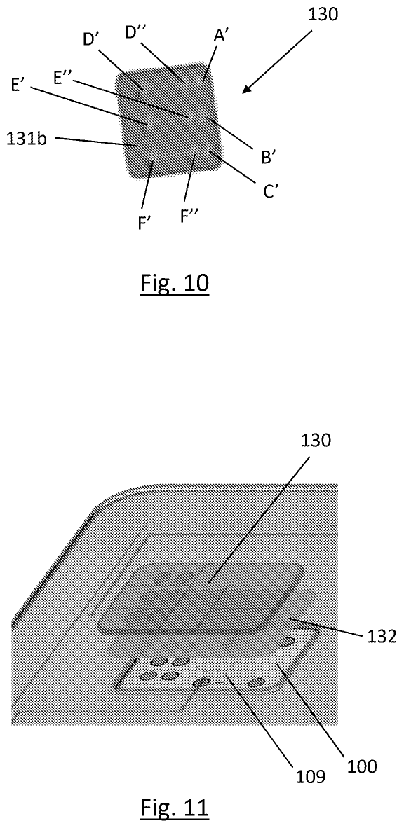

FIGS. 9 and 10 show respectively a front view and a back view of the lead-frame 130. The upper major surface 131a of the lead-frame 130 is identical with a conventional lead-frame in that it is partitioned into six electrically conductive areas, marked as A, B, C, D, E and F in FIG. 9. On the bottom major surface 131b of the lead-frame 130 are formed electrical connection point A′, B′, C′, D′, E′ and F′, each in electrical connection respectively with the electrically conductive areas A, B, C, D, E and F. However, because of the arrangement and positioning of the connection points 112a-f on the front major surface 109 of the IC module 100, and as shown in FIG. 10, each of the electrically conductive areas D′, E′ and F′ is connected on the bottom major surface 131b of the lead-frame 130 to a respective electrical connection point D′, E′ and F′ on the bottom major surface 131b of the lead-frame 130. The electrical connection points A′, B′, C′, D′, E′ and F′ are positioned and arranged such that, when the lead-frame 130 is fixedly engaged with the front major surface 109 of the IC module 100, they are in electrical connection with the connection points 112a-f on the front major surface 109 of the IC module 100.

As shown in more detail in FIG. 11, to facilitate physical and electrical connection between the lead-frame 130 and the front major surface 109 of the IC module 100, an electrically conductive adhesive material, e.g. an anisotropic conductive (ACF) film or tape 132, is positioned between the front major surface 109 of the IC module 100 and the bottom major surface 131b of the lead-frame 130. Upon lamination, the IC module 100 and the lead-frame 130 are fixedly engaged and electrically connected with each other via the ACF tape 132, to form the IC card 200 as shown in FIG. 12.

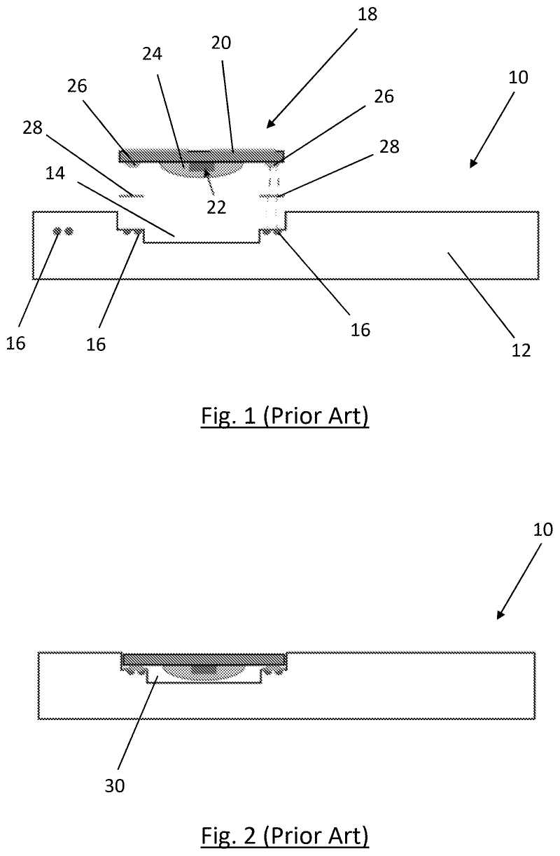

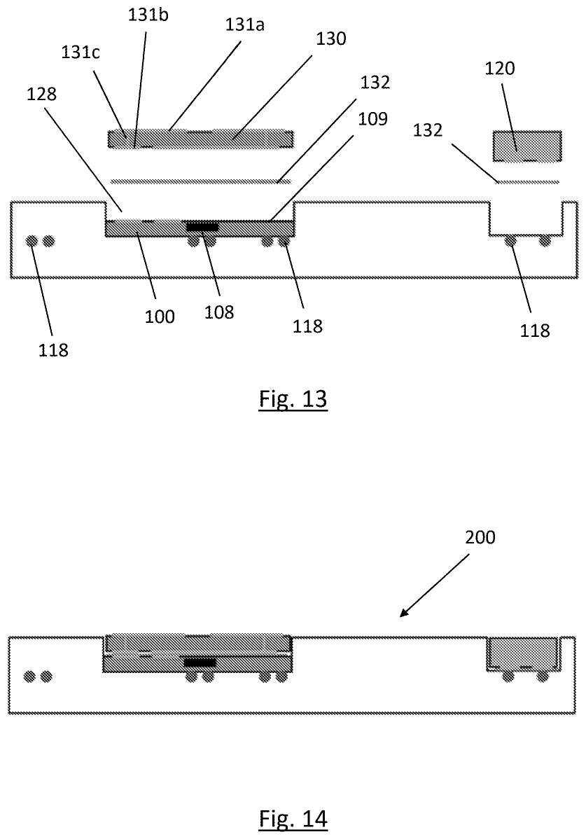

As shown in FIGS. 13 and 14, in forming the multi-interface IC card 200 according to the present invention, the IC module 100 with the IC chip 108 is first formed in the multi-layered structure 126, and electrically connected with the loop antenna coil 118. The lead-frame 130 is then fixedly engaged and electrically connected with the IC module 100 (and thus with the IC card 200) via the ACF tape 132. Similarly, the second communication interface 120 is also fixedly engaged and electrically connected with the electric wires 121 (and thus with the IC card 200) via an ACF tape 132. It can be seen that, when compared with the prior art arrangement shown in FIGS. 1 and 2, the cavity 128 is of one level only and has straight side walls surrounding the cavity 128 for receiving the IC module 100 and the lead-frame 130, thus simplifying the milling process. In addition, the front major surface 109 of the IC module 100 is generally flat, thus facilitating support of and engagement with the lead-frame 130. Furthermore, both the physical and electrical connection between the IC module 100 and the loop antenna coil 118 are also enhanced.

It should be understood that the above only illustrates examples whereby the present invention may be carried out, and that various modifications and/or alterations may be made thereto without departing from the spirit of the invention.

It should also be understood that certain features of the invention, which are, for clarity, described in the context of separate embodiments, may be provided in combination in a single embodiment. Conversely, various features of the invention which are, for brevity, described in the context of a single embodiment, may also be provided separately or in any appropriate sub-combinations.

1. An integrated circuit (IC) module, including:
a first substrate layer with a hole,
an integrated circuit (IC) chip received within said hole of said first substrate layer, and
a second substrate layer fixedly connected with said first substrate layer and electrically connected with said IC chip,
wherein said second substrate layer includes a first substantially planar major surface and a second substantially planar major surface which are substantially parallel with each other,
wherein said first major surface of said second substrate layer includes a first plurality of connection points electrically connected with said IC chip,
wherein said first plurality of connection points are electrically connected with a second plurality of connection points on said second major surface of said second substrate layer, and
wherein said IC module is in the shape of a prism, a cylinder, or an elliptical cylinder.

2. The module of claim 1, wherein a first connection point and a second connection point of said second plurality of connection points on said second major surface of said second substrate layer are adapted to be electrically connected with a first communication interface.

3. The module of claim 2, wherein said first communication interface includes a loop antenna coil.

4. The module of claim 2, wherein a third connection point and a fourth connection point of said second plurality of connection points on said second major surface of said second substrate layer are adapted to be electrically connected with a second communication interface.

5. The module of claim 4, wherein said second communication interface includes a finger-print sensor.

6. A multi-interface integrated circuit (IC) card, including:
at least one IC module according to claim 1, at least a third substrate layer fixedly engaged with said IC module, and
a lead-frame fixedly engaged with said third substrate and electrically connected with said IC module,
wherein said third substrate layer includes a first communication interface electrically connected with a first connection point and a second connection point of said second plurality of connection points on said second major surface of said second substrate layer of said IC module and a second communication interface electrically connected with a third connection point and a fourth connection point of said second plurality of connection points on said second major surface of said second substrate layer of said IC module.

7. The card of claim 6, wherein said first communication interface includes a loop antenna coil.

8. The card of claim 6, wherein said second communication interface includes a finger-print sensor or a light-emitting diode (LED) module.

9. The card of claim 6, wherein said card includes a cavity with substantially straight side walls within which said IC module and at least a part of said lead-frame are received.

10. The card of claim 6, wherein said lead-frame is fixedly engaged with said third substrate and electrically connected with said IC module via an anisotropic conductive film or tape.

11. The card of claim 6, wherein said second communication interface is fixedly engaged with said third substrate and electrically connected with said IC module via an anisotropic conductive film or tape.

12. A method of forming an integrated circuit (IC) module, including:
providing a first substrate layer with a hole,
positioning an integrated circuit (IC) chip within said hole of said first substrate layer, and
providing a second substrate layer with a first substantially planar major surface and a second substantially planar major surface which are substantially parallel with each other,
fixedly connecting said second substrate layer with said first substrate layer,
electrically connecting a first plurality of connection points on said first major surface of said second substrate layer with said IC chip,
wherein said first plurality of connection points are electrically connected with a second plurality of connection points on said second major surface of said second substrate layer, and
wherein said IC module is in the shape of a prism, a cylinder, or an elliptical cylinder.

13. The method of claim 12, further including electrically connecting a first connection point and a second connection point of said second plurality of connection points on said second major surface of said second substrate layer with a first communication interface.

14. The method of claim 13, wherein said first communication interface includes a loop antenna coil.

15. The method of claim 13, further including electrically connecting a third connection point and a fourth connection point of said second plurality of connection points on said second major surface of said second substrate layer with a second communication interface.

16. The method of claim 15, wherein said second communication interface includes a finger-print sensor.

17. A method of forming an integrated circuit (IC) card, including:
fixedly engaging an IC module formed according to claim 12 with a third substrate layer,
electrically connecting a loop antenna coil of third substrate layer with a first connection point and a second connection point of said second plurality of connection points on said second major surface of said second substrate layer of said IC module,
fixedly engaging a lead-frame with said third substrate, and
electrically connecting said lead-frame with said IC module.

18. The method of claim 17, wherein said first communication interface includes a loop antenna coil.

19. The method of claim 18, wherein said second communication interface includes a finger-print sensor.

20. The method of claim 17, wherein said card includes a cavity with substantially straight side walls in which said IC module and at least a part of said lead-frame are received.

21. The method claim 17, further including fixedly engaging said lead-frame with said third substrate and electrically connecting said lead-frame with said IC module via an anisotropic conductive film or tape.

22. The method of claim 17, further including fixedly engaging said second communication interface with said third substrate and electrically connecting said second communication interface with said IC module via an anisotropic conductive film or tape.
